(19) United States
(12) Patent Application Publication
(10) Pub. No.: US 2018/0117813 A1
(43) Pub. Date: May 3, 2018

(54) MOLDING APPARATUS INCLUDING A COMPRESSIBLE STRUCTURE

(71) Applicant: ASM Technology Singapore Pte Ltd, Singapore (SG)

(72) Inventors: Shu Chuen HO, Singapore (SG); Teng Hock KUAH, Singapore (SG); Jiapei DING, Singapore (SG); Jian Xiong SU, Singapore (SG); Ravindra RAGHAVENDRA, Singapore (SG)

(21) Appl. No.: 15/341,733

(22) Filed: Nov. 2, 2016

(51) Int. Cl. B29C 45/43; B29C 45/14; B29C 45/17; B29C 45/26; H01L 23/29

(52) U.S. Cl. CPC B29C 45/43; B29C 45/14336; B29C 45/14639; B29K 2105/20; B29C 45/2602; H01L 23/293; B29C 45/1701

(57) ABSTRACT

The invention provides a molding apparatus comprising a first mold part operative to hold a semiconductor substrate, and a second mold part having a main surface facing the first mold part. The first and second mold parts are movable relative to each other between an open arrangement and a closed arrangement. The main surface comprises portions defining a mold cavity, and a recess at least partially surrounding the mold cavity. The main surface also comprises a compressible structure located within the recess, wherein at least a portion of the compressible structure extends out of the recess towards the first mold part and is compressible into the recess when the compressible structure contacts the semiconductor substrate in the closed arrangement. The second mold part also comprises one or more air conduits operative to introduce compressed air into the mold cavity.

### TECHNICAL FIELD

The present invention relates to a molding apparatus, as well as a method of molding a semiconductor substrate.

### BACKGROUND

A conventional molding apparatus typically includes ejection pins to release a molded package from a mold cavity. Multiple layers of plates and support plugs are required to move the ejection pins between a retract position (during molding) and an eject position (to release the molded package from the mold cavity). Therefore, the conventional molding apparatuses are typically bulky, heavy, and difficult to fabricate and handle.

Ultra-thin packages are becoming increasingly popular. An ultra-thin package is much less rigid compared to conventional packages. Accordingly, more ejection pins would be required to avoid package delamination during the ejection process. Hence, conventional molding apparatus for forming ultra-thin packages would require more components or parts to accommodate the increased number of ejection pins, resulting in higher costs.

### SUMMARY

The present invention thus seeks to provide an improved molding apparatus which is able to address or alleviate the abovementioned issues. The improved molding apparatus removes or reduces the need for numerous ejection pins as well as multiple layers of plates and support plugs, resulting in a less complex structure and in reduced costs.

Accordingly, the invention provides a molding apparatus comprising a first mold part operative to hold a semiconductor substrate. The molding apparatus further comprises a second mold part having a main surface facing the first mold part. The first and second mold parts are movable relative to each other between an open arrangement and a closed arrangement. The main surface comprises portions defining a mold cavity, and a recess at least partially surrounding the mold cavity and operative to be at least partially within the perimeter of the semiconductor substrate held on the first mold part. The main surface also comprises a compressible structure located within the recess, wherein at least a portion of the compressible structure extends out of the recess towards the first mold part and is compressible into the recess when the compressible structure contacts the semiconductor substrate in the closed arrangement. The second mold part further comprises one or more air conduits operative to introduce compressed air into the mold cavity to separate the molded semiconductor substrate from the second mold part.

The present invention also provides a method of molding a semiconductor substrate. The method includes providing the semiconductor substrate over a first mold part, the first mold part having a main surface facing a second mold part, the main surface comprising portions defining a mold cavity and a recess at least partially surrounding the mold cavity and operative to be at least partially within the perimeter of the semiconductor substrate held on the first mold part. The method may also include moving the first mold part and a second mold part from an open arrangement, wherein a compressible structure located within the recess has a portion extending out of the recess towards the first mold part, towards each other to a closed arrangement, wherein the compressible structure contacts the semiconductor substrate to compress the compressible structure into the recess. The method may additionally include introducing compressed air into the mold cavity to separate the molded semiconductor substrate from the second mold part.

### BRIEF DESCRIPTION OF THE DRAWINGS

The invention will be better understood with reference to the detailed description when considered in conjunction with the non-limiting examples and the accompanying drawings, in which:

FIG. 1 shows a top planar schematic layout of the apparatus according to a first embodiment of the present invention.

FIG. 2 shows the top planar schematic layout of the apparatus shown in FIG. 1 with the openings of a plurality of air conduits and a plurality of compressible structures visible over the bottom mold part.

FIG. 3A is a cross-sectional side view of the apparatus along the line L1 illustrated in FIG. 2.

FIG. 3B is the cross-sectional side view of the apparatus shown in FIG. 3A with semiconductor substrates placed onto the holding portions of the bottom mold part.

FIG. 4A is a cross-sectional side view of the apparatus along the line L2 illustrated in FIG. 2.

FIG. 4B is the cross-sectional side view of the apparatus shown in FIG. 4A with semiconductor substrates placed onto the holding portions of the bottom mold part.

FIG. 5 is a magnified cross-sectional side view of a portion of the top mold part along line L1 shown in FIG. 2 according to one configuration of the first embodiment.

FIG. 6A is a magnified cross-sectional side view of the apparatus of FIG. 5 (along line L2 shown in FIG. 2), when the compressible structures are spaced apart from the semiconductor substrates.

FIG. 6B is the magnified cross-sectional side view of the apparatus shown in FIG. 6A, when the compressible structures are in contact with the semiconductor substrates.

FIG. 7A is a magnified cross-sectional side view of a portion of the top mold part along line L1 shown in FIG. 2 according to a further configuration of the first embodiment.

FIG. 7B is a magnified cross-sectional side view of the apparatus of FIG. 7A (along line L2 shown in FIG. 2 of the configuration).

FIG. 8 is a magnified cross-sectional side view of a portion of top mold part along line L1 shown in FIG. 2 according to yet another configuration of the first embodiment.

FIG. 9A shows the cross-sectional side view of the apparatus along line L1 shown in FIG. 2 with the holding portions of the bottom mold part moved relative to the middle portion of the bottom mold part so that the semiconductor substrates are secured or clamped by flanges of the middle portion onto the holding portions.

FIG. 9B shows a cross-sectional side view of the apparatus along line L1 shown in FIG. 2 with the semiconductor substrates in contact with the compressible structures.

FIG. 9C shows a cross-sectional side view of the apparatus along line L1 shown in FIG. 2 during generation of a vacuum in the mold cavities when the bottom mold part and the top mold part are in the closed arrangement.

FIG. 9D is a top planar cross-sectional schematic layout of the apparatus during the generation of vacuum as shown in FIG. 9C.

FIG. 9E shows a cross-sectional side view of the apparatus along line L1 shown in FIG. 2 after the top mold part has moved relative to the holding portions of the bottom mold part, until the substrates on the holding portions are in contact with the main surface of the mold piece of the top mold part.

FIG. 9F shows a cross-sectional side view of the apparatus along line L1 shown in FIG. 2 when the mold compound is used to form mold cap structures on the semiconductor substrates.

FIG. 10A shows a cross-sectional side view of the apparatus along line L1 shown in FIG. 2 when compressed air is introduced through the air conduits in order to separate the molded semiconductor substrates from the mold piece of the top mold part.

FIG. 10B shows a cross-sectional side view of the apparatus along line L1 shown in FIG. 2 as the bottom mold part and the top mold part move away from each other.

FIG. 10C is a top planar cross-sectional schematic layout of the apparatus corresponding to FIG. 10B as the bottom mold part and the top mold part move away from each other.

FIG. 10D shows a cross-sectional side view of the apparatus along line L1 shown in FIG. 2 when compressed air is no longer supplied through the conduits, and the molded semiconductor substrates are separated from the main surface of the top mold part.

FIG. 10E shows a cross-sectional side view of the apparatus along line L1 shown in FIG. 2 the apparatus is in the open arrangement.

FIG. 11A is a top planar cross-sectional schematic layout of an apparatus according to a second embodiment of the present invention.

FIG. 11B is another top planar cross-sectional schematic of the apparatus shown in FIG. 11A when the compressed air is introduced from the air conduits to separate the molded semiconductor substrates from the mold cavities of the top mold part.

FIG. 12 illustrates a method of molding a semiconductor substrate.

### DETAILED DESCRIPTION

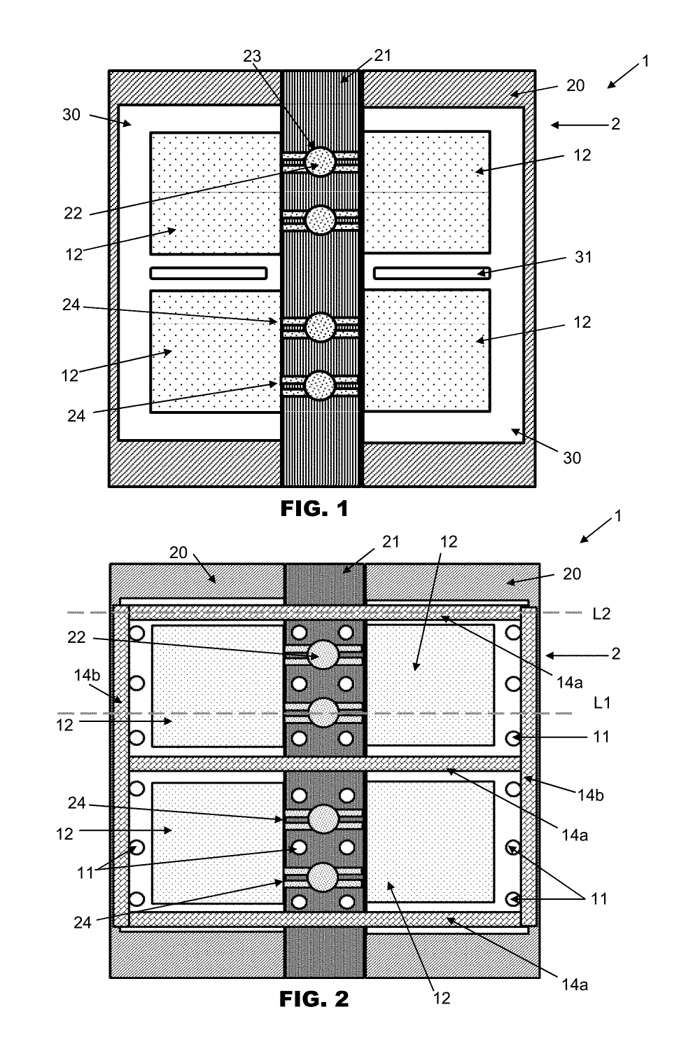

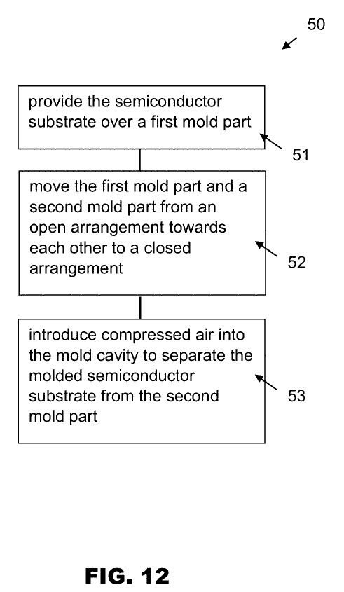

An embodiment of the invention will now be described with reference to FIGS. 1, 2, 3A-3B, 4A-4B, 5, 6A-6B, 7A-7B, 8, 9A-9F, 10A-10E. Further, FIGS. 11A-11B relate to another embodiment of the invention. FIG. 12 relates to a method according to an embodiment of the present invention. In order to reduce clutter and improve clarity, not all similar features found in each figure are labelled.

FIG. 1 shows a top planar schematic layout of the apparatus 1 according to a first embodiment of the present invention. Semiconductor substrates 30 are arranged on holding portions 20 of a bottom mold part 2 (which may also be referred to as a first mold part) of the apparatus 1. The two holding portions 20 are separated by the middle portion 21 of the bottom mold part 2 extending from one side of the bottom mold part 2 to another opposing side of the bottom mold part 2. Each of the two semiconductor substrates 30 are arranged on a respective holding portion 20. Each semiconductor substrate 30 may include a slot 31. As shown in FIG. 1, each slot 31 is between a respective pair of mold cavities 12. FIG. 1 shows a plurality of runners 24 leading from each pot 23 over a respective plunger 22 to the lateral sides of the middle portion 21 for dispensing or introducing the mold compound (not shown in FIG. 1) over the semiconductor substrates 30 placed on the holding portions 20.

FIG. 2 shows the top planar schematic layout of the apparatus 1 shown in FIG. 1 with the openings of a plurality of air conduits 11 and a plurality of compressible structures 14a, 14b visible over the bottom mold part 2. The apparatus 1 includes three parallel compressible structures 14a, and two parallel compressible structures 14b that are transverse to the three parallel compressible structures 14a. The compressible structures 14a are perpendicular to the compressible structures 14b. The compressible structures 14a run over the middle portion 21. As shown in FIG. 2, a pair of mold cavities 12 is surrounded by two compressible structures 14a as well as portions of two compressible structures 14b. Each mold cavity 12 is thus surrounded by a plurality of compressible structures 14a, 14b. The compressible structures 14a, 14b are arranged to be directly above the semiconductor substrates 30 on the holding portions 20. A center compressible structure 14a is arranged to be directly above the slots 31 of the semiconductor substrates 30, and is useful for covering the slots 31 in order to prevent air leakage from the slots 31. For example, air may leak into the mold cavities 12 through the slots 31 during the generation of vacuum or after vacuum has been generated in the mold cavities 12, or air may leak out from the mold cavities 12 through the slots 31 when compressed air is being introduced into the mold cavities 12. The openings of the air conduits 11 may be above the middle portion 21 as well as above one side portion of the semiconductor substrates 30. The plungers 22 and the associated runners 24 are not directly under the compressible structures 14a, 14b.

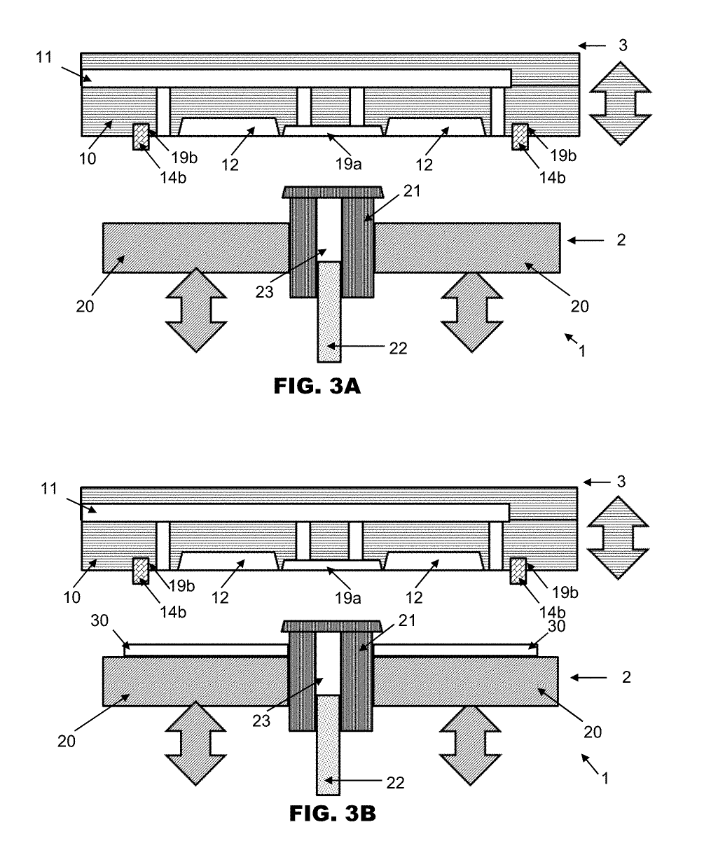

FIG. 3A is a cross-sectional side view of the apparatus 1 along the line L1 illustrated in FIG. 2. The apparatus include a second mold part 3 in addition to the first mold part 2. The second mold part 3 may also be referred to as a top mold part. The bottom mold part 2 includes holding portions 20, each holding portion 20 comprising a planar surface facing the top mold part 3. The bottom mold part 2 also includes a middle portion 21 extending vertically away from the planar surface of the holding portions 20 towards the top mold part 3. The plunger 22 shown in FIG. 3A is partially received in the pot 23 of the middle portion 21.

The top mold part 3 comprises a mold piece 10 having a main surface facing the bottom mold part 2. The main surface has portions defining mold cavities 12 as well as a central cavity 19a. The mold piece 10 of the top mold part 3 also includes the air conduits 11 extending to the main surface as well as to the central cavity 19a. The air conduits 11 are air channels connecting the main surface of the mold piece 10 and the central cavity 19a to a compressor or air supply which provides compressed air. The air conduits 11 are also connected to a vacuum generator or a vacuum pump. The main surface also has portions defining recesses 19b to hold the compressible structures 14b. The compressible structures 14b protrudes from the main surface of the mold piece 10 towards the bottom mold part 2. As shown in FIG. 3A, the mold cavities 12, the openings of the air conduits 11 on the main surface, and the recesses 19b holding the compressible structures 14b are situated at different regions of the main surface. The mold cavities 12 are defined in a first region of the main surface of the top mold part 3. The recesses 19b holding the compressible structures 14b are defined at a second region at the two lateral sides of the main surface. The openings of the air conduits 11 on the main surface are situated at a third region between the first region and the second region.

When the bottom mold part 2 and the top mold part 3 are in an open arrangement, i.e. when the bottom mold part 2 and the top mold part 3 are spaced apart, the semiconductor substrates 30 may be placed onto the holding portions 20 of the bottom mold part 2 as shown in FIG. 3B. Each holding portion 20 may hold one semiconductor substrate 30. The semiconductor substrates 30 are separated from each other by the middle portion 21 and the pots 23 for receiving the plungers 22. The semiconductor substrates 30 may for instance be lead frames, and may have circuitry formed on a surface of each semiconductor substrate 30. The semiconductor substrates 30 may also be organic substrates. The semiconductor substrates 30 may be arranged on the holding portion 20 of the bottom mold part 2 with the surfaces having the circuitry facing up towards the top mold part 3. The top mold part 3 comprises the mold piece 10 with the air conduits 11, the mold cavities 12, the central cavity 19a, and the recesses 19b, as well as the compressible structures 14b as depicted in FIG. 3A.

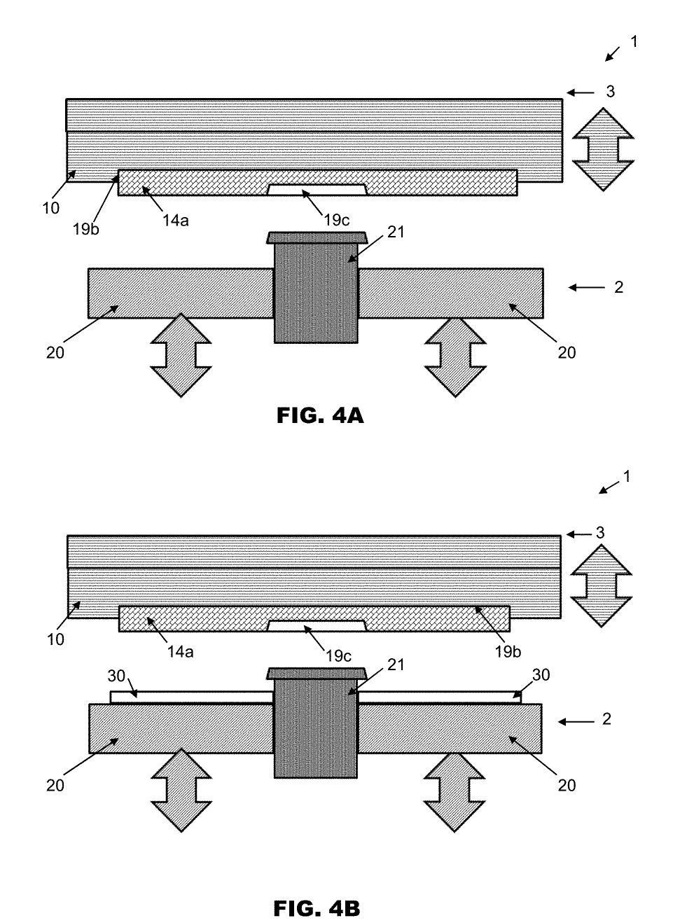

FIG. 4A is a cross-sectional side view of the apparatus 1 along the line L2 illustrated in FIG. 2. FIG. 4A corresponds to FIG. 3A whereby there are no semiconductor substrates 30 arranged on the holding portions 20. The air conduits 11 and the mold cavities 12 are not visible in FIG. 4A. The compressible structures 14a, of which only one is visible in FIG. 4A, extend across the main surface of the top mold part 3 to join the two lateral compressible structures 14b shown in FIG. 3A. Each compressible structure 14a is held in a recess 19b. The compressible structures 14a may each be patterned to form a receiving cavity 19c which is aligned with the central cavity 19a formed on the mold piece 10 of the top mold part 3. The compressible structures 14a protrudes from the main surface of the mold piece 10 towards the bottom mold part 2. The pot 23 of the middle portion 21 is not visible in FIG. 4A.

FIG. 4B shows the cross-sectional side view of the apparatus 1 along the line L2 with the semiconductor substrates 30 arranged on the holding portions 20.

The bottom mold part 2 and the top mold part 3 are gradually moved relative to each other from an open arrangement as shown in FIGS. 3A-B, FIGS. 4A-B to a closed arrangement. Both the bottom mold part 2 and the top mold part 3 may be moved towards each other, or only the bottom mold part 2 may move while the top mold part 3 remains stationary. Alternatively, only the top mold part 3 may move while the bottom mold part 2 remains stationary.

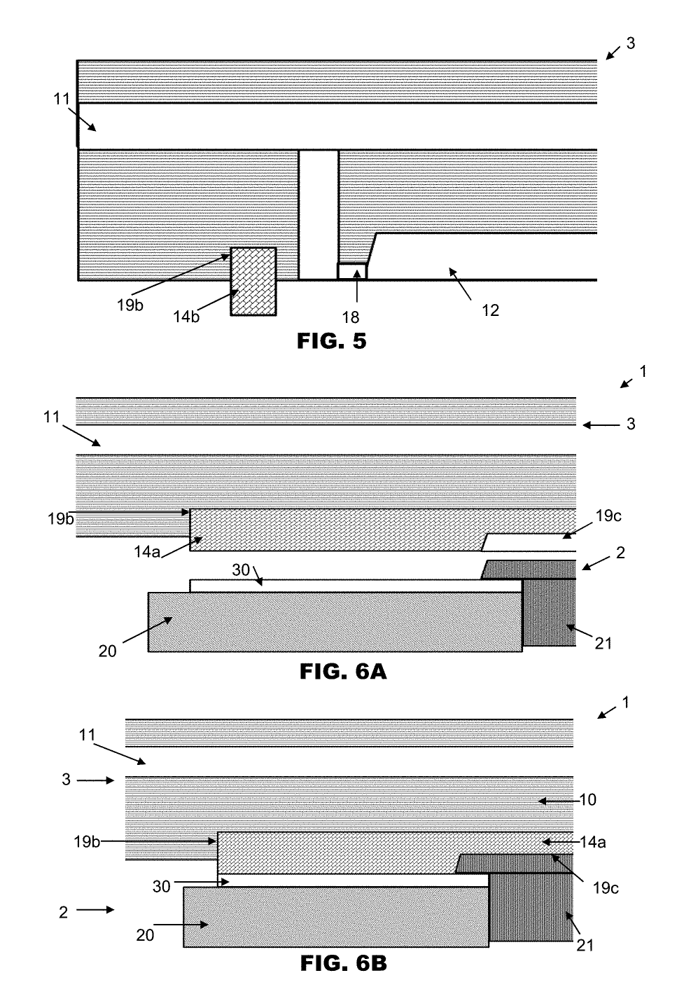

FIG. 5 is a magnified cross-sectional side view of a portion of the top mold part 3 along line L1 shown in FIG. 2 according to one configuration of the first embodiment. As shown in FIG. 5, each compressible structure 14b may be a single piece of compressible material such as an elastomer. The recess 19b holds the elastomer. The Young's Modulus of the elastomer may be any value in the range of about 0.0005 GPa to about 0.05 GPa. The elastomer may be a silicone such as vinyl-methyl-silicone (VMQ) or a fluorosilicone, a nitrile such as acrylonitrile butadiene rubber (NBR), a propylene such as ethylene propylene diene monomer (M-class) rubber (EPM rubber), a perfluoro-elastomer such as Kalrez® perfluoroelastomer or FFKM, a fluoroelastomer such as FKM (Viton®), a neoprene etc. The low Young's Modulus of the material allows for large deformation under a relatively mild compressive force. FIG. 5 also shows that the top mold 3 includes an air vent 18 connecting an air conduit 11 to the mold cavity 12.

FIG. 6A is a magnified cross-sectional side view of the apparatus 1 of FIG. 5 (along line L2 shown in FIG. 2), when the compressible structures 14a are spaced apart from the semiconductor substrates 30. The bottom mold part 2 and the top mold part 3 are shown. The compressible structure 14a may be the same elastomer shown in FIG. 5. As shown in FIG. 6A, the elastomer is a single piece of material received in a recess 19b of the mold piece 10. The compressible structure 14a shown in FIG. 6A is uncompressed and protrudes out of the recess 19b. The compressible structure 14a is directly over the semiconductor substrate 30, which is clamped by the middle portion 21 and the holding portion 20. The receiving cavity 19c defined in the compressible structure 14a is directly above the flange portion of the middle portion 21.

FIG. 6B shows the compressible structure 14a coming into contact with the semiconductor substrate 30 when the bottom mold 2 and the top mold 3 shown in FIG. 6A are moved from the open arrangement to the closed arrangement. The flange portion of the middle portion 21 is received by the receiving cavity 19c, while the semiconductor substrate 30 remains clamped between the flange portion of the middle portion 21 and the holding portion 20. The compressible structure 14a remains in contact with mold piece 10 and is held by the recess 19b.

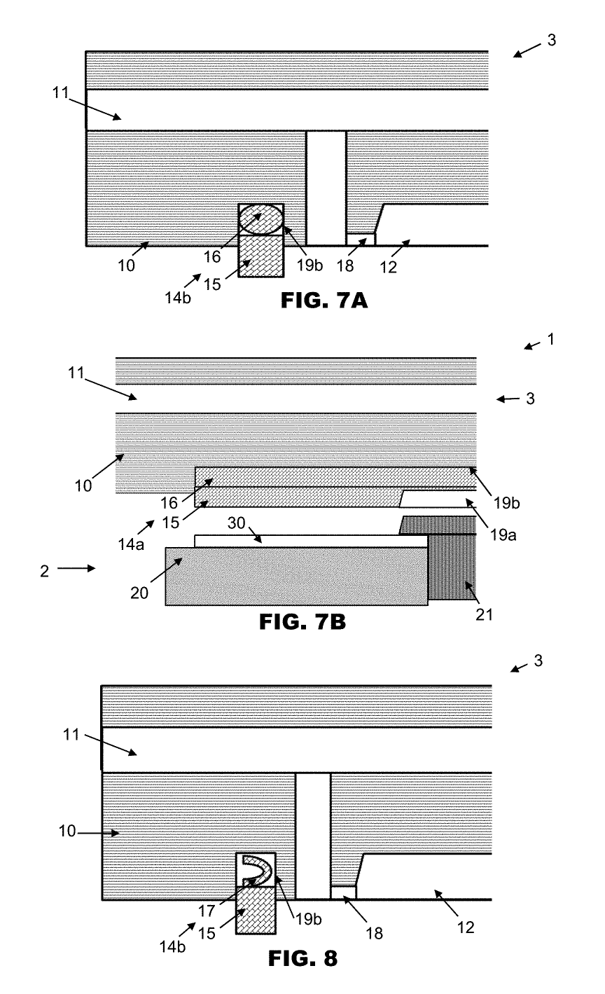

FIG. 7A is a magnified cross-sectional side view of a portion of the top mold part 3 along line L1 shown in FIG. 2 according to a further configuration. Each compressible structure 14b may include an elastomer 16 and a rigid structure 15 in contact with the elastomer 16. The rigid structure 15 may include a material such as a metal such as stainless steel, steel, copper, or aluminum. The rigid structure 15 may alternatively include a polymer such as polytetrafluoroethylene (PTFE), or a polymer composite material. The elastomer 16 may be above the rigid structure 15, and may attach or hold the rigid structure 15 to the recess 19b. In other words, a first end of the elastomer 16 is attached to an inner surface of the recess 19b defined on the mold piece 10 of the top mold part 3, while a second opposing end of the elastomer 16 is attached to the rigid structure 15. The air vent 18 joins the air conduit 11 to the mold cavity 12.

FIG. 7B is a magnified cross-sectional side view of the apparatus 1 of FIG. 7A (along line L2 shown in FIG. 2 of the configuration). In addition to the top mold part 3, the bottom mold part 2 is also shown. The compressible structure 14a includes the rigid structure 15 which is being held by the elastomer 16 to the mold piece 10. From FIG. 7B, it can be seen that the rigid structure 15 protrudes out of the recess 19b while the elastomer 16 is contained within the recess 19b. A receiving cavity 19c is defined on the rigid structure 15. The receiving cavity 19c is directly over a flange of the middle portion 21, and is shaped to fit the middle portion 21. The vertically stacked arrangement comprising the elastomer 16 and the rigid structure 15 is directly over the semiconductor substrate 30, which is clamped by the flange of the middle portion 21 and the holding portion 20.

FIG. 8 is a magnified cross-sectional side view of a portion of top mold part 3 along line L1 shown in FIG. 2 according to yet another configuration of the first embodiment. The compressible structure 14b may include a spring 17 and a rigid structure 15. While not shown in FIG. 8, the compressible structure 14a may also have a similar structure as compressible structure 14b. The compressible structure 14a may also include a further spring and a further rigid structure. The spring 17 may for instance be a steel cantilever spring or a steel spiral spring. The spring 17 may be over the rigid structure 15, thereby forming a vertically stacked arrangement. A first end of the spring 17 is attached to an inner surface of the recess 19b defined on the mold piece 10 of top mold part 3, while a second opposing end of the spring 17 is attached to the rigid structure 15. The air vent 18 joins the air conduit 11 to the mold cavity 12.

In all the three configurations of the first embodiment described herein, the compressible structures 14a, 14b, the semiconductor substrates 30, the top mold part 3, and the bottom mold part 2 form an effective seal in an enclosed space including the mold cavities 12 as well as the pots 23. The enclosed space is defined by the top mold part 3, the compressible structures 14a, 14b, the bottom mold part 2 (which includes the middle portion 21), and the semiconductor substrates 30. A vacuum generator or pump is coupled to the air conduits 11 to generate a vacuum in the enclosed space. The absolute pressure of the vacuum may reach less than 1 Torr. The generation of the vacuum may commence when the compressible structures 14a, 14b come into contact with the semiconductor substrates 30. As the semiconductor substrates 30 press onto the compressible structures 14a, 14b, the resilient compressible structures 14a, 14b push back against the semiconductor substrates 30, thereby creating an effective seal.

For the second and third configurations, the rigid structure 15 reduces adhesion between the compressible structures 14a, 14b and the semiconductor substrates 30, especially at molding temperatures at or above 175°. Organic substrates typically have a top layer of solder mask (or solder resist) which is usually a composite material including epoxy resin and one or more inorganic fillers. Directly contacting the elastomers 16 with an organic substrate 30 may result in the elastomers 16 being adhered to the top layer of the organic substrate 30, which makes separation of the elastomers 16 from the organic substrate 30 difficult, and which may potentially lead to reliability issues. By using the rigid structure 15 as an intermediate structure to contact the organic substrates 30, the problem of adhesion may be avoided or alleviated.

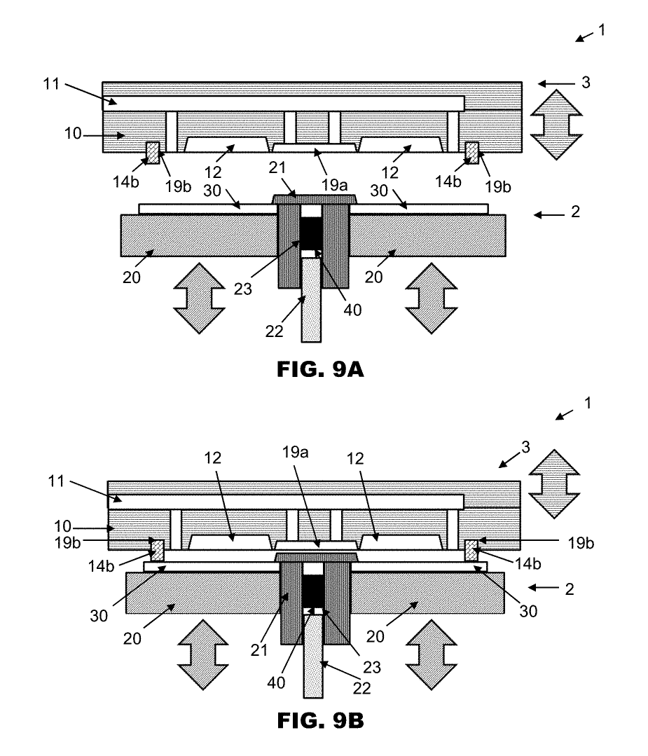

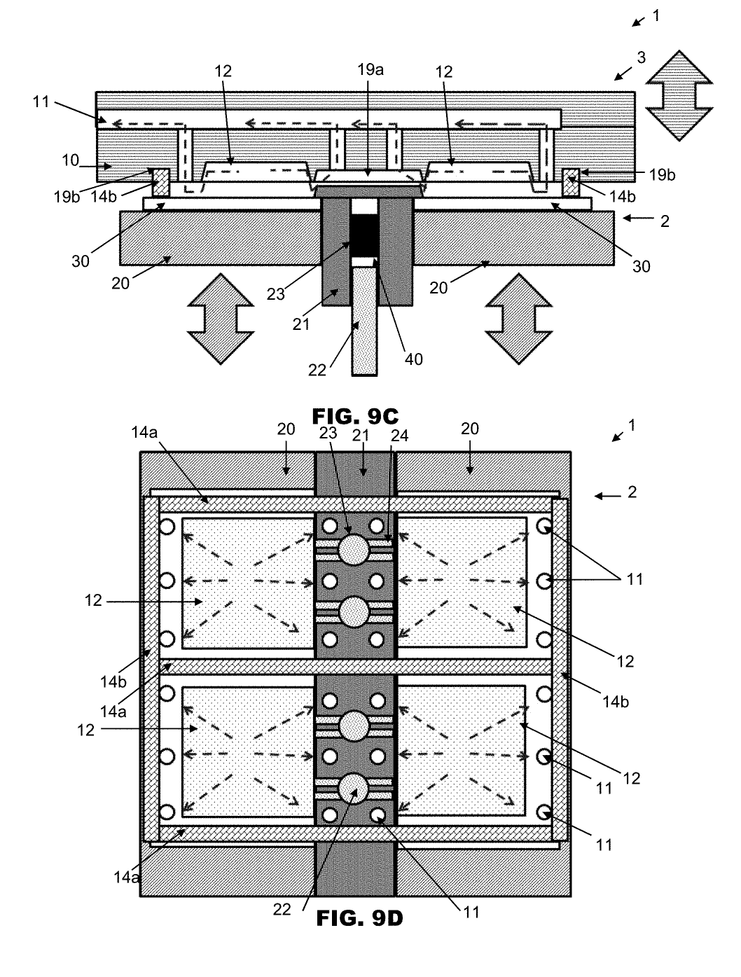

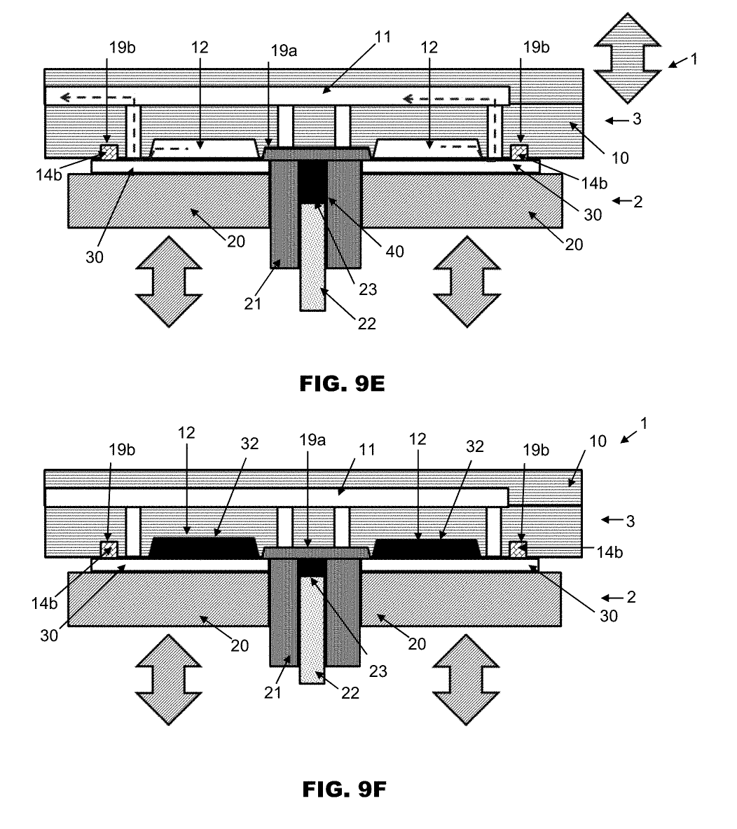

FIG. 9A shows the cross-sectional side view of the apparatus 1 with the holding portion 20 of the bottom mold part 2 moved relative to the middle portion 21 of the bottom mold part 2 so that the semiconductor substrates 30 are secured or clamped by flanges of the middle portion 21 onto the holding portions 20. A mold compound 40 is introduced into the pots 23 of the middle portion 21 above the plungers 22.

FIG. 9B shows a cross-sectional side view of the apparatus 1 with the semiconductor substrates 30 in contact with the compressible structures 14b. The bottom mold part 2 and the top mold part 3 are moved closer together from the open arrangement shown in FIG. 9A to the closed arrangement in FIG. 9B, in which the compressible structures 14b are in contact with the semiconductor substrates 30. Comparing FIG. 9A and FIG. 9B, the distance between the planar surface of the holding portion 20 of the bottom mold 2 and the main surface of the top mold 3 in FIG. 9B is smaller compared to the distance in FIG. 9A. While not shown in FIG. 9B, the compressible structures 14a are also in contact with the semiconductor substrates 30.

FIG. 9C shows a cross-sectional side view of the apparatus 1 during generation of a vacuum in the mold cavities 12 when the bottom mold part 2 and the top mold part 3 are in the closed arrangement. The generation of vacuum is caused by the removal of air from a space sealed by the top mold part 3, the compressible structures 14b, the bottom mold part 2 (which includes the middle portion 21), and the semiconductor substrates 30. The dashed arrows indicate the direction of air flow. As shown in FIG. 9C, air is removed from the space defined by the compressible structures 14b at the sides, the semiconductor substrates 30 (on the holding portions 20) and the middle portion 21 at the bottom, as well as the mold piece 10 at the top, including the central cavity 19a and the mold cavities 12. Air is also removed from the pot 23 for holding the mold compound 40 above the plunger 22 as shown in FIG. 9C. The air is removed through the air conduits 11 in the mold piece 10 of the top mold part 3 by the vacuum pump or vacuum generator coupled to the air conduits 11.

The gap between the main surface of the top mold portion 3 and the substrate 30 during generation of vacuum may be any value between about 1 mm and about 30 mm, which is higher compared to a gap formed in an apparatus with just the air vent 18 but without the compressible structures 14a, 14b. The air in the mold cavities 12 and the pots 23 may be removed at a faster rate, leading to more rapid generation of vacuum.

FIG. 9D is a top planar cross-sectional schematic layout of the apparatus 1 during the generation of vacuum. The dashed arrows in FIG. 9D indicate the flow of air. As shown in FIG. 9D, air flows from the mold cavities 12 to the air conduits 11, thus generating a vacuum in the mold cavities 12, as well as the runners 24 and pots 23 that are located above the plungers 22 in the middle mold portion 21 between the holding portions 20. The compressible structures 14a, 14b function as seals by contacting the semiconductor substrates 30, thus helping to generate the vacuum in the mold cavities 12, runners 24, and pots 23 above the plungers 22 in the middle mold portion 21.

FIG. 9E shows a cross-sectional side view of the apparatus 1 after the top mold part 3 has moved relative to the holding portions 20 of the bottom mold part 2, until the substrates 30 on the holding portions 20 are in contact with the main surface of the mold piece 10 of the top mold part 3. A compressive force is applied to the compressible structures 14b and compressible structures 14a (not shown in FIG. 9E) through the relative movement of the bottom mold part 2 towards the top mold part 3, thereby compressing the compressible structures 14a, 14b. As shown in FIG. 9E, the interface between the compressible structures 14b and the semiconductor substrates 30 may be substantially flush with the main surface of the mold piece 10. There is no gap between the main surface of the top mold part 3 and top surfaces of the semiconductor substrates 30. The semiconductor substrate 30 is now clamped between the holding portions 20, the flange of the middle portion 21, the compressible structures 14a, 14b, and the main surface of the top mold part 3. Air is still being evacuated from the mold cavities 12 through the air vents 18 (not shown in FIG. 9E) and the air conduits 11 by the vacuum generator or pump. The top flange of the middle mold portion 21 is received by the central cavity 19a of the mold piece 10. The compressible structures 14a, 14b are compressed until they are fully within the recesses 19b. The mold compound 40 is still in the pots 23 above the plungers 21.

FIG. 9F shows the injection of the mold compound 40 to form mold cap structures 32 on the semiconductor substrates 30. The mold cap structures 32 with the underlying semiconductor substrates 30 may be collectively referred to as molded semiconductor substrates. The plungers 22 are pushed into the pots 23 of the middle portion 21 to introduce or inject the mold compound 40 into the mold cavities 12 to form the mold cap structures 32. The compressible structures 14b, as well as the compressible structures 14a (not shown in FIG. 9F), contained within the recesses 19b are compressed between the mold piece 10 and the semiconductor substrates 30, thus maintaining an effective seal around the mold cavities 12. The substrate 30 is held onto the holding portions 20. The vacuum generated is maintained at a stable level during the introduction of the mold compound 40 into the mold cavities 12. The flange of the middle portion 21 is fully received in the central cavity 19a and cooperates with the mold piece 10 to prevent loss of vacuum through openings of the air conduits 11 in the central cavity 19a. The flange of the middle portion 21 is also fully received in the receiving cavities 19c of the compressible structures 14a (not shown in FIG. 9F), and cooperates with the compressible structures 14a to prevent the loss of vacuum within the mold cavities 12.

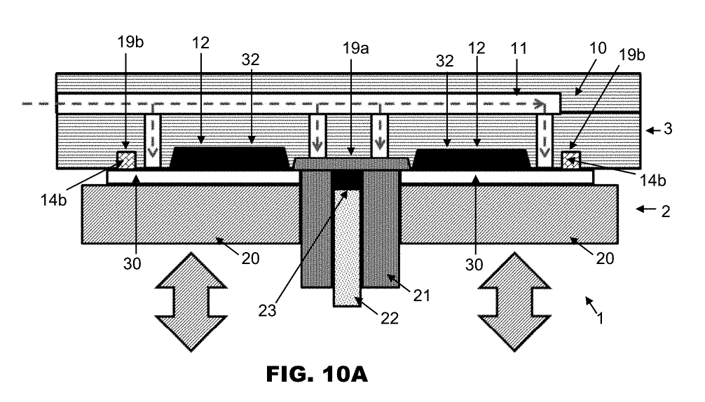

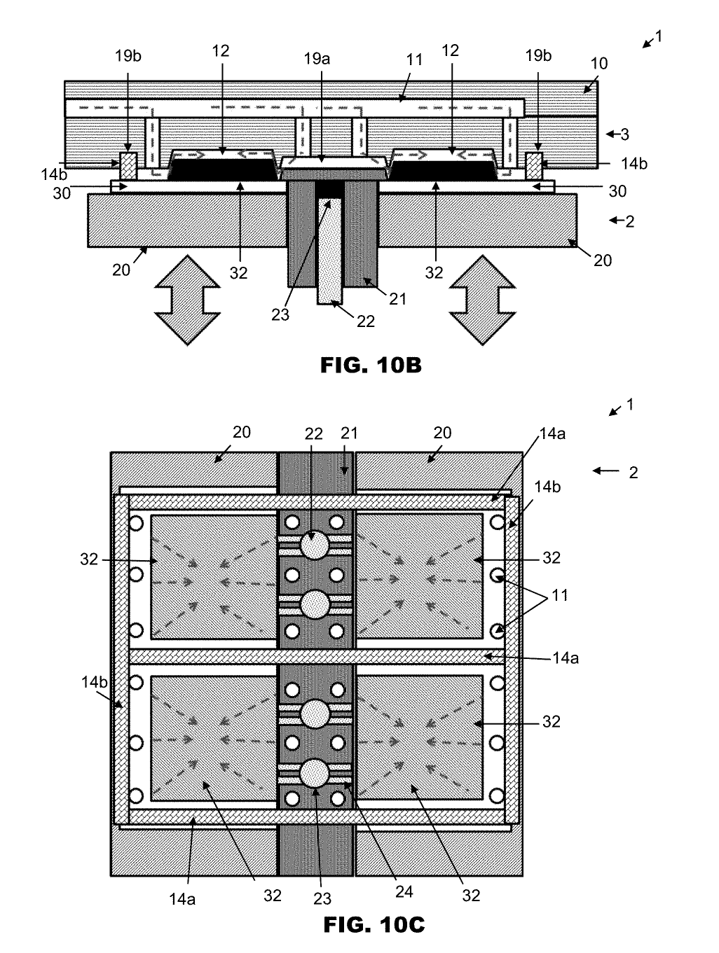

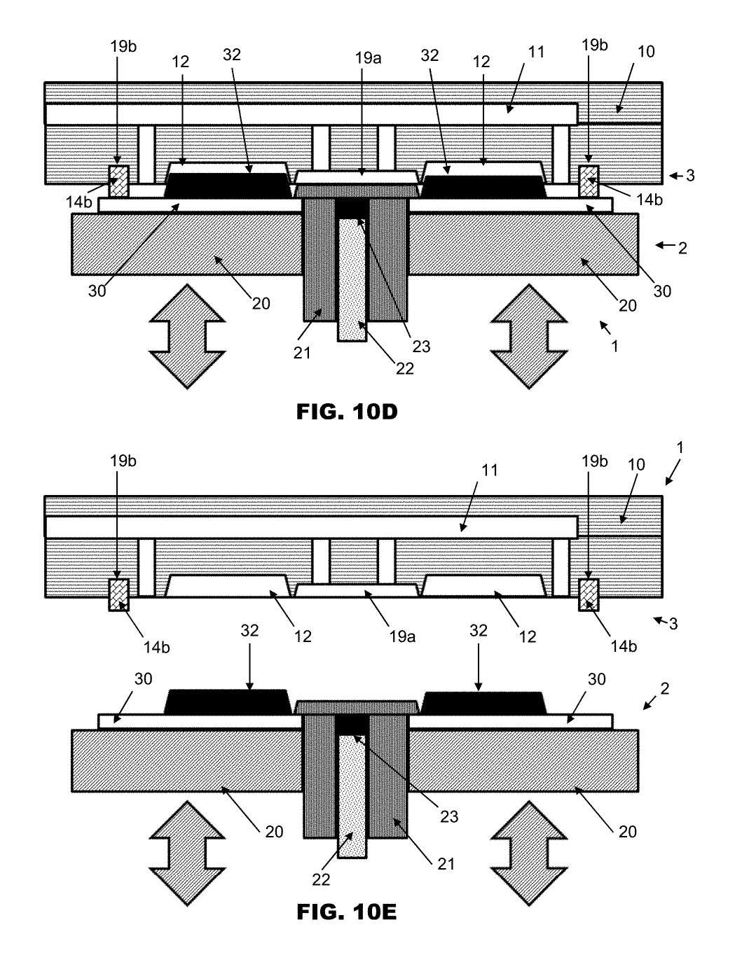

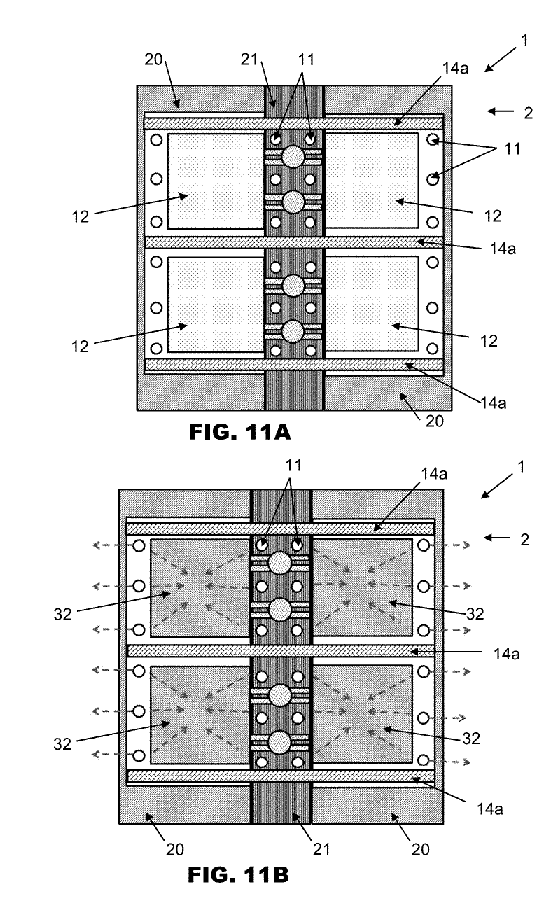

FIG. 10A shows the introduction of compressed air through the air conduits 11 in order to separate the molded semiconductor substrates including the mold cap structures 32 and the semiconductor substrates 30, from the mold piece 10 of the top mold part 3, as the bottom mold part 2 and the top mold part 3 of the apparatus 1 move apart relative to each other. The flow of the compressed air is indicated by dashed arrows. The compressed air is also introduced to the central cavity 19a and pushes against the middle portion 21. As the holding portions 20 of the bottom mold part 2 move away from the mold piece 10 of the top mold part 3, the compressible structures 14b as well as the compressible structures 14a (not shown in FIG. 10A) in the recesses 19b expand. An end portion of each plunger 22 may remain in the respective pot 23 of the middle portion 21.

FIG. 10B shows the separation of the bottom mold part 2 and the top mold part 3 as they move apart. The mold cap structures 32 and the semiconductor substrates 30 would usually adhere to the surfaces of the mold piece 10. Therefore, the compressed air from the air conduits 11 is introduced to push against the semiconductor substrates 30 in order to separate the semiconductor substrates 30 from the surfaces of the mold piece 10. As the top mold part 3 and the bottom mold part 2 move away from each other, the compressed air from the air conduits 11 pushes against and exerts a high pressure onto molded surfaces of the semiconductor substrates 30 and the middle portion 21, as indicated by the dashed arrows. Thus, the compressed air “peels off” the molded surfaces of the semiconductor substrates 30 from the surfaces of the mold piece 10, by separating the semiconductor substrates 30 from the surfaces of the mold piece 10, starting from the edges of the mold cap structures 32 towards the center of the mold cap structures 32. In other words, a gap between the molded surface of the semiconductor substrates 30 (i.e. the surface with the mold cap structures 32 and facing the mold piece 10) and the mold piece 10 increases from zero to several millimeters. A gap is also formed between the central cavity 19a and the middle portion 21, as the middle portion 21 is separated from the mold piece 10. The gaps are formed beginning from the air conduits 11, to the edges of the mold cap structures 32, and finally towards the center of the mold cap structures 32. The compressed air flows through the gaps to the molded surface of the semiconductor substrates 30. The compressible structures 14b, as well as the compressible structures 14a (not shown in FIG. 10D), expand as the holding portions 20 move away from mold piece 10, thus remaining in contact with the semiconductor substrates 30 and are sufficiently compressed to maintain the sealing effect. The introduction of the compressed air via the air conduits 11 onto the molded surface of the semiconductor substrates 30 exerts a pressure of about 5 to about 7 bar onto the molded surface of the semiconductor substrates 30. The opposing side of the semiconductor substrates 30 which is facing the holding portions 20 is at a pressure of about 1 bar (atmospheric pressure). The pressure difference between the opposing sides of the semiconductor substrate 30 generates a uniformly distributed downward force on the semiconductor substrates 30. The compressed air enters into the mold cavities 12 at a draft angle through the gaps between the mold piece 10 and the mold cap structures 32, and helps to detach the molded cap substrates 32 from the mold piece 10. Accordingly, the compressed air separates the molded semiconductor substrates from the second mold part 3. The end portion of each plunger 22 remains in the respective pot 23 of the middle portion 21.

FIG. 10C is a top planar cross-sectional schematic layout of the apparatus 1 corresponding to FIG. 10B. The dashed arrows indicate the flow of the compressed air from the air conduits 11 over the middle mold 21, and from the air conduits 11 over the sides of holding portions 20, to the respective center of the mold cap structures 32. As highlighted above, the compressible structures 14a, 14b continue to seal the mold cavities 12. The end portion of each plunger 22 remains in the respective pot 23 of the middle portion 21, although the mold compound 40 is no longer dispensed through the runners 24.

In FIG. 10D, compressed air is no longer supplied through the conduits 11, and the molded semiconductor substrates including the semiconductor substrates 30 and mold cap structures 32, have been separated from the main surface of the mold piece 10 of the top mold part 3. The compressible structures 14b, as well as compressible structures 14a (not shown in FIG. 10D), remain in contact with the semiconductor substrates 30 on the holding portions 20, and the space between the top mold part 3 and the bottom mold part 2 remains sealed by the compressible structures 14b as well as compressible structures 14a (not shown in FIG. 10D) held in the recesses 19b. There is a gap between the mold cap structures 32 and mold piece 10 in the mold cavities 12, as well as between the middle portion 21 and the mold piece 10 in the central cavity 19a. The end portion of each plunger 22 remains in the respective pot 23 of the middle portion 21.

FIG. 10E shows the apparatus 1 in the open arrangement, as the top mold part 3 and the bottom mold part 2 move further apart from each other. The distance between the planar surface of the holding portion 20 of the bottom mold part 2 and the main surface of the mold piece 10 of the top mold part 3 in the open arrangement is greater than the distance between the planar surface and the main surface in the closed arrangement. The compressible structures 14b, as well as the compressible structures 14a (not shown in FIG. 10E), are isolated from the semiconductor substrate 30, and are fully expanded, i.e. the compressible structures 14a, 14b are in the uncompressed state. The top mold part 3, which includes the mold piece 10 with the central cavity 19a, the recesses 19b, the mold cavities 12, and the air conduits 11, as well as the compressible structures 14a, 14b, is fully separated from the bottom mold part 2, which includes the holding portions 20, the middle portion 21, the pots 23 and the plungers 22. The molded semiconductor substrate, which includes the semiconductor substrates 30 and the mold cap structures 32 on the semiconductor substrates 30, may be easily removed from the holding portions 20. The middle portion 21 may be moved up relative to the holding portions 20 to further facilitate the removal of the molded semiconductor substrates. The cull, which includes the leftover solidified molding compound in the pots 23, are removed and discarded, before a fresh batch of mold compound 40 is introduced into the pots 23 of the middle portion 21 for subsequent molding.

FIG. 11A is a top planar cross-sectional schematic layout of an apparatus 1 according to a second embodiment of the present invention. As shown in FIG. 11A, the apparatus 1 includes three parallel compressible structures 14a over the semiconductor substrates 30 on the holding portions 20. The three parallel compressible structures 14a may each include a receiving cavity 19c to receive the middle portion 21. The center compressible structure 14a may be used to cover any slots 31 which may be present in the semiconductor substrates 30. There are no compressible structures over the lateral sides of the semiconductor substrates 30, i.e. parallel to the rows of openings of the air conduits 11 that are over the semiconductor substrates 30.

There are only two compressible structures 14a on two opposing sides of each mold cavity 12, i.e. a first compressible structure 14a on a first side of the mold cavity 12, and a second compressible structure 14a on a second side of the mold cavity 12 opposing the first side. There are no other compressible structures joining the two compressible structures 14a on the two opposing sides. Accordingly, the mold cavities 12 are not fully surrounded by the compressible structures 14a when the compressible structures 14a are in contact with the semiconductor substrates 30 when the top mold part 3 and the bottom mold part 2 are moved into the closed arrangement. Openings at the sides of the apparatus 1 (i.e. with no compressible structures) allow air to pass between the apparatus 1 and the external environment, even when the top mold part 3 and bottom mold part 2 are in the closed arrangement, and the three parallel compressible structures 14a are in contact with the semiconductor substrates 30. The other features of the second embodiment are similar to that of the first embodiment. The apparatus 1 includes the bottom mold part 2 with the holding portions 20, the middle portion 21 between the holding portions 20, the plungers 22, the pots 23 for storing the mold compound and for receiving the plungers 22, and the runners 24 leading from the pots 23. The apparatus 1 also includes the top mold part 3 including the mold piece 10 with the air conduits 11, the mold cavities 12, the central cavity 19a for receiving the middle portion 21, and the recesses 19b for holding the compressible structures 14a.

FIG. 11B is another top planar cross-sectional schematic of the apparatus 1 shown in FIG. 11A when the compressed air is introduced from the air conduits 11 to separate the molded semiconductor substrates, which includes the mold cap structures 32 and the semiconductor substrates 30, from the mold cavities 12 of the top mold part 3. The mold cap structures 32 are formed after injection of the mold compound from the pots 23 in the middle portion 21 onto the semiconductor substrates 30 held on the holding portions 20. The injection may be carried out by movement of the plungers 22 into the pots 23. The mold compound flows through the runners 24 onto the semiconductor substrates 30. The dashed arrows in FIG. 11B indicate the flow of the compressed air. The absence of the compressible structures 14b at the sides mean that the space between the top mold part 3 and the bottom mold part 2, which includes the mold cavities 12, is not fully sealed, and the compressed air is able to escape from the apparatus 1 from the sides as shown in FIG. 11B.

In some cases, it may be necessary for the mold cap structures 32 to be formed near the edges of the substrates 30. In these cases, it may not be practical to include compressible members 14b at over the lateral sides of the substrates 30. Advantageously, the apparatus 1 according to the second embodiment may have a simpler structure with reduced number of components, leading to lower costs of fabrication and operation.

As long as the pressure exerted by and the flow rate of the compressed air introduced via the air conduits 11 are sufficiently high to provide a positive pressure on the molding surfaces of the semiconductor substrates 30, i.e. the surfaces on which the mold cap structures 32 are formed, the ejection force would be sufficient to separate the mold cap structures 32 from the mold cavities 12.

In general, the pressure exerted on the molding surface of the semiconductor substrate 30 may be any value in the range of about 5 bars to about 7 bars, while the pressure on the non-molding surface of the semiconductor substrate 30 opposing the molding surface may be about 1 bar (atmospheric pressure). Assuming that the mold cap structures 32 formed by the apparatus 1 according to any one of both embodiments is about 300 mm by 100 mm, the net ejection force may have a minimum value of 2400 kg (30×10×2×(5−1)) and a maximum value of 3600 kg (30×10×2×(7−1)). As the adhesion strength between the mold cavities 12 (coated by DryLub) and the mold cap structures 32 is typically around 0.1 MPa, the force required is around 600 kg (30×10×2×1). Accordingly, the safety margin works out to be about 300% ((2400−600)/600).

FIG. 12 illustrates a method 50 of molding a semiconductor substrate. The method includes, in 51, providing the semiconductor substrate over a first mold part, the first mold part having a main surface facing a main surface of a second mold part, the main surface of the second mold part comprising portions defining a mold cavity and a recess at least partially surrounding the mold cavity and operative to be at least partially within the perimeter of the semiconductor substrate held on the first mold part. The recess may also be fully within the perimeter of the semiconductor substrate. The method may also include, in 52, moving the first mold part and a second mold part from an open arrangement, wherein a compressible structure located within the recess has a portion extending out of the recess towards the first mold part. The first and second mold parts move towards each other to a closed arrangement, wherein the compressible structure contacts the semiconductor substrate to compress the compressible structure to be at least partially within the recess. The compressible structure may also be compressed to be fully within the recess. The method may additionally include, in 53, introducing compressed air into the mold cavity to separate the molded semiconductor substrate from the second mold part. The method may be used in conjunction with the apparatuses shown in FIGS. 1, 2, 3A-B, 4A-B, 5, 6A-B, 7A-B, 8, 9A-F, 10A-E, as well as FIGS. 11A-11B.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A molding apparatus comprising:
a first mold part operative to hold a semiconductor substrate;
a second mold part having a main surface facing the first mold part; wherein the first and second mold parts are movable relative to each other between an open arrangement and a closed arrangement,
wherein the main surface comprises portions defining a mold cavity, and a recess at least partially surrounding the mold cavity and operative to be at least partially within the perimeter of the semiconductor substrate held on the first mold part; and
a compressible structure located within the recess, wherein at least a portion of the compressible structure extends out of the recess towards the first mold part and is compressible into the recess when the compressible structure contacts the semiconductor substrate in the closed arrangement;
wherein the second mold part further comprises one or more air conduits operative to introduce compressed air into the mold cavity to separate the molded semiconductor substrate from the second mold part.

2. The molding apparatus according to claim 1, further comprising:
one or more further compressible structures to form a plurality of compressible structures surrounding the mold cavity.

3. The molding apparatus according to claim 1, further comprising:
a further compressible structure;
wherein the compressible structure is on a first side of the mold cavity, and the further compressible structure is on a second side of the cavity opposite the first side.

4. The molding apparatus according to claim 1, further comprising:
a vacuum pump coupled to the one or more air conduits.

5. The molding apparatus according to claim 1,
wherein the compressible structure comprises an elastomer.

6. The molding apparatus according to claim 5,
wherein the elastomer is any one selected from a group consisting of silicones, nitriles, propylenes, perfluoroelastomers, and neoprenes.

7. The molding apparatus according to claim 5,
wherein the compressible structure further comprises a rigid structure in contact with the elastomer.

8. The molding apparatus according to claim 1,
wherein the compressible structure comprises a spring, and a rigid structure in contact with the spring.

9. The molding apparatus according to claim 1, wherein the recess is fully within the perimeter of the semiconductor substrate.

10. The molding apparatus according to claim 1, wherein the compressible structure is compressible to be fully within the recess.

11. A method of molding a semiconductor substrate, the method comprising:
providing the semiconductor substrate over a first mold part, the first mold part having a main surface facing a second mold part, the main surface comprising portions defining a mold cavity and a recess at least partially surrounding the mold cavity and operative to be at least partially within the perimeter of the semiconductor substrate held on the first mold part;
moving the first mold part and a second mold part from an open arrangement, wherein a compressible structure located within the recess has a portion extending out of the recess towards the first mold part, towards each other to a closed arrangement, wherein the compressible structure contacts the semiconductor substrate to compress the compressible structure into the recess
introducing a mold compound into a mold cavity defined by the main surface of the second mold part to form a molded semiconductor substrate comprising the semiconductor substrate and a mold cap structure on the semiconductor substrate;
separating the first mold part and the second mold part; and
introducing compressed air into the mold cavity to separate the molded semiconductor substrate from the second mold part.
